(19) United States
(12) Patent Application Publication
(10) Pub. No.: US 2020/0075830 A1
(43) Pub. Date: Mar. 5, 2020

(54) THERMOELECTRIC DEVICE

(71) Applicant: GENTHERM GMBH, Odelzhausen (DE)

(72) Inventors: Rüdiger Spillner, Augsburg (DE); Viktor Martel, Augsburg (DE); Margarita Preciado Rincon, Augsburg (DE); Sandra Schicho, München (DE); Vladimir Jovovic, Pasadena, CA (US)

(21) Appl. No.: 16/468,101

(22) PCT Filed: Dec. 12, 2017
(86) PCT No.: PCT/DE2017/000419

§ 371 Date: Jun. 10, 2019

(30) Foreign Application Priority Data
Dec. 12, 2016 (DE) 10 2016 014 686.9

(51) Int. Cl. H01L 35/32; H01L 35/30; H01L 35/34; H01L 35/08; B60N 3/10; B60N 2/56; F25B 21/02

(52) U.S. Cl. CPC H01L 35/32; H01L 35/30; H01L 35/34; F25B 2321/023; B60N 3/104; B60N 2/5692; F25B 21/02; H01L 35/08

(57) ABSTRACT

The invention relates to a thermoelectric device (10) with several, differently-doped and electrically-conductively interconnected semiconductors (12), at least one carrier substrate (14) arranged on a first side of the semiconductors (12), and at least one carrier substrate (16a-16d) arranged on a second side, opposite the first side, of the semiconductors (12), wherein at least one carrier substrate (14, 16a-16d) arranged on the first side or the second side of the semiconductors (12) has at least one recess (18a-18d, 20a-20d) which extends through the carrier substrate (14, 16a-16d) and is surrounded by substrate material, and which is designed to receive a fastening means (22a-22d).

The invention relates to a thermoelectric device with several, differently-doped and electrically-conductively interconnected semiconductors, at least one carrier substrate which is arranged on a first side of the semiconductors, and at least one carrier substrate which is arranged on a second side of the semiconductors opposite the first side.

The invention also relates to a cup holder for a vehicle, with a receiving device, which is designed to receive a drinking vessel and provides a temperature control space for the drinking vessel, and one or more thermoelectric devices, which are coupled with the temperature control space in a heat-transferring manner.

The invention further relates to a temperature control device for seats—in particular, vehicle seats—having a conveying device which is designed to convey a fluid—in particular, air—to a temperature control area, and to a temperature control device which has one or more thermoelectric devices and is designed to control the temperature of the fluid to be conveyed to the temperature control area.

The invention further relates to a method for producing a thermoelectric device referred to above, with the steps of firmly bonding the several, differently-doped semiconductors with several electrically-conductive connectors arranged on a first carrier substrate and firmly bonding the several, differently-doped semiconductors with several electrically-conductive connectors arranged on a second carrier substrate.

If a potential difference between two contact poles is generated in a generic thermoelectric device, heat is transported from a first side to a second side of the thermoelectric device.

Consequently, the two sides of the thermoelectric device therefore have different temperatures. The thermoelectric device thus produces a temperature gradient from the applied electrical voltage. In this case, the thermoelectric device operates as a Peltier element.

If a temperature difference is generated in a generic thermoelectric device between the first side and the second side of the thermoelectric device, electrical charge is transported from the first electrical contact pole to the second electrical contact pole of the thermoelectric device. Consequently, the two electrical contact poles therefore have different electrical potentials. The thermoelectric device thus generates an electrical voltage from the applied temperature gradient. In this case, the thermoelectric device operates as a Seebeck element.

Thermoelectric devices must regularly be attached to objects with which heat exchange is to take place. Known thermoelectric devices are small enough that attachment to the outer edges is sufficient to ensure satisfactory heat exchange over the entire contact area of the thermoelectric device and the object. Systems are known, for example, in which the outer edges of the thermoelectric device are clamped to the object.

However, applications are becoming increasingly known which require the use of large-area thermoelectric devices. In the case of large-area thermoelectric devices, however, attachment to the outer edges is not suitable for ensuring a satisfactory heat exchange over the entire contact area of the thermoelectric device and the object.

The aim underlying the invention is thus to create a possibility of being able to attach large-area thermoelectric devices to objects without excessively impairing the heat exchange between the thermoelectric device and the object.

The aim is achieved by a thermoelectric device of the type mentioned at the outset, wherein at least one carrier substrate arranged on the first side or the second side of the semiconductors has at least one recess which extends through the carrier substrate and is surrounded by substrate material, and which is designed to receive the fastening means.

The invention makes use of the knowledge that the thermoelectric device can be attached to an object by means of a fastening means at a position in the middle of the thermoelectric device as a result of the recess extending through the carrier substrate and surrounded by substrate material. The need for attachment to the side edges of the thermoelectric device is thus overcome. In this way, a sufficiently homogeneous pressure distribution over the entire surface of the thermoelectric device can be achieved, in order to ensure a satisfactory heat exchange over the entire contact area of the thermoelectric device and the object. As a result of such an attachment of the thermoelectric device, the thermoelectric device can also be designed to have a large area, without excessively impairing the heat exchange between the thermoelectric device and the object. The fastening means may, for example, be a screw, a bolt, a pin, or a clamp.

The thermoelectric device is preferably designed as a Peltier element and/or as a Seebeck element. A Peltier element is a flat semiconductor element which heats up on one side when an electrical voltage is applied, and cools on an opposite side. A Seebeck element is a flat semiconductor element that generates an electrical voltage when one of its sides is heated and an opposite side is cooled.

In a preferred embodiment of the thermoelectric device according to the invention, at least one carrier substrate arranged on the first side of the semiconductors and at least one carrier substrate arranged on the second side of the semiconductors each have at least one recess which extends through the carrier substrate and is surrounded by substrate material, and which is designed to receive a fastening means. Since both at least one carrier substrate arranged on the first side of the semiconductors and at least one carrier substrate arranged on the second side of the semiconductors each have a recess, the carrier substrates can respectively be attached to the object directly—for example, using a fastening means which extends through the respective recess.

In another embodiment of the thermoelectric device according to the invention, the at least one recess of the at least one carrier substrate arranged on the first side of the semiconductors and the at least one recess of the at least one carrier substrate arranged on the second side of the semiconductors are arranged in alignment with one another. As a result of the aligned arrangement of the recesses, a fastening means can extend through the carrier substrates on both sides of the semiconductors. The attachment of the thermoelectric device to the object is thus significantly simplified.

Furthermore, the thermoelectric device according to the invention is, advantageously, further developed in that only one carrier substrate is arranged on the first side of the semiconductors and/or on the second side of the semiconductors. The only one carrier substrate preferably has a rectangular or square basic shape and extends essentially over the entire width and/or over the entire length of the thermoelectric device.

In another embodiment of the thermoelectric device according to the invention, several carrier substrates are arranged on the first side of the semiconductors and/or on the second side of the semiconductors. The several carrier substrates arranged on one side are preferably of the same size. The sum of the areas of the several carrier substrates arranged on one side of the semiconductors is preferably smaller than the total area of the thermoelectric device. In particular, several or all of the several carrier substrates arranged on one side of the semiconductors are each arranged in a corner and/or on an edge of the thermoelectric device, or form at least a portion of a corner or of an edge of the thermoelectric device. The several carrier substrates arranged on one side of the semiconductors are preferably arranged at a distance from one another.

Also preferred is a thermoelectric device according to the invention in which the number of the carrier substrates arranged on the first side of the semiconductors is smaller than the number of carrier substrates arranged on the second side of the semiconductors. For example, only one carrier substrate is arranged on the first side of the semiconductors, and two, three, four, five, six, seven, eight, nine, ten, or more than ten carrier substrates are arranged on the second side of the semiconductors.

In a preferred embodiment of the thermoelectric device according to the invention, the number of the recesses of the at least one carrier substrate arranged on the first side of the semiconductors and the number of recesses of the several carrier substrates arranged on the second side of the semiconductors are identical. The recesses of the at least one carrier substrate arranged on the first side of the semiconductors and the recesses of the several carrier substrates arranged on the second side of the semiconductors are preferably designed to be in alignment with one another, so that a fastening means can in each case extend through a carrier substrate on the first side of the semiconductors and a carrier substrate on the second side of the semiconductors.

Furthermore, a thermoelectric device according to the invention is advantageous in which the several carrier substrates arranged on the second side of the semiconductors each have only one recess, and the recesses of the several carrier substrates arranged on the second side of the semiconductors are arranged substantially in the center of the respective carrier substrate. The central arrangement of the recesses results in improved pressure distribution across the carrier substrate surface. In this way, excessive mechanical stresses are avoided, and the risk of damage—in particular, during the assembly process—is considerably reduced.

Preferred also is a thermoelectric device according to the invention, in which the several carrier substrates arranged on the second side of the semiconductors are arranged at a distance from one another. The sum of the open areas resulting from the distancing and the surfaces of the several carrier substrates arranged on the second side of the semiconductors substantially corresponds to the total area of the at least one carrier substrate arranged on the first side of the semiconductors.

In a preferred embodiment of the thermoelectric device according to the invention, the several carrier substrates arranged on the second side of the semiconductors each extend over a semiconductor group. The semiconductor group comprises a portion of the total number of semiconductors of the thermoelectric device, wherein the semiconductor groups are covered by a carrier substrate arranged on the second side of the semiconductors. The semiconductors of a semiconductor group are preferably arranged equidistantly from one another.

In a development of the thermoelectric device according to the invention, several or all semiconductor groups each extend over an area of the same size and/or have an identical number of semiconductors. In this way, the same fastening means and the same mounting parameters, such as matching tightening torques of the fastening means designed as screws, can be used. The assembly is thus simplified, and the production costs are reduced.

A thermoelectric device according to the invention in which the semiconductor groups are electrically-conductively interconnected is, moreover, preferred. The semiconductor groups are preferably connected in series. For this purpose, the thermoelectric device, in particular, has several, electrically-conductive, group-connecting bridges. Preferably, a first semiconductor group and a last semiconductor group each have an electrical contact pole serving as a terminal, which is designed to be connected to an electrical conductor. With respect to a series connection, one or more further semiconductor groups may be arranged between the first semiconductor group and the last semiconductor group, wherein the electrically-conductive connection between the semiconductor groups connected in series is implemented by the group-connecting bridges. In this way, the need for internal electrical lines is also overcome, thereby reducing the risk of damage and speeding up the manufacture of the thermoelectric device.

In another preferred embodiment of the thermoelectric device according to the invention, several or all semiconductor groups are sealed circumferentially with a sealing material, which reduces or prevents the transport of moisture to the semiconductors. Moisture can lead to corrosion of the metallic connectors of the semiconductor elements, as a result of which the function of the thermoelectric device can be impaired. Strong corrosion can even lead to a malfunction of the thermoelectric device. The corrosion process is significantly slowed down or even avoided by the sealing material.

Also advantageous is a thermoelectric device according to the invention, in which sealing material is arranged between adjacent semiconductor groups, which sealing material reduces or prevents the transport of moisture to the semiconductors. The sealing material between adjacent semiconductor groups also results in a higher stability, and thus in a higher mechanical strength of the thermoelectric device. If desired for the intended purpose, the sealing material between adjacent semiconductor groups can also increase the stiffness of the thermoelectric device as a result of suitable material selection.

In another embodiment of the thermoelectric device according to the invention, the sealing material is designed as silicone or comprises silicone. Silicone is particularly suitable as sealing material, because, on the one hand, it provides an effective protection against the ingress of moisture and, on the other, can be introduced into the thermoelectric device in a fluid state. By introducing the silicone in the fluid state, it can adapt to the geometries to be sealed before curing or drying of the silicone takes place.

In another preferred embodiment of the thermoelectric device according to the invention, one recess, several recesses, or all recesses each have a seal, which prevents or reduces the transport of moisture to the semiconductors. If two recesses of different carrier substrates are arranged in alignment with one another, the seal preferably extends over the aligned recesses. Without a corresponding seal, the recesses would allow moisture to enter the thermoelectric device, and thus reach the semiconductors and the metal bridges which interconnect the semiconductors. In order to reduce the associated risk of corrosion, the seals arranged in the recesses allow effective reduction or even prevention of ingress of moisture.

The thermoelectric device according to the invention is also advantageously further developed in that the one or more seals are designed to be annular. The one or more seals preferably have at least one section whose outer diameter substantially corresponds to the diameter of the recess. Annular seals allow the sealing of a round recess and, at the same time, the reception of a round fastening means, such as a screw, a pin, a bolt, or a round clamp, which extends through the seal.

In an advantageous embodiment of the thermoelectric device according to the invention, the one or more seals each support a carrier substrate arranged on the first side of the semiconductors and a carrier substrate arranged on the second side of the semiconductors against one another. For this purpose, the one or more seals preferably also extend in sections between two opposite carrier substrates so that a contact surface for the carrier substrates forms. The one or more seals thus act as support elements. The support elements may also have pores in sections. Since the one or more seals each support a carrier substrate arranged on the first side of the semiconductors and a carrier substrate arranged on the second side of the semiconductors against one another, the stability and the mechanical strength of the thermoelectric device are further increased.

Preference is also given to a thermoelectric device according to the invention in which the one or more seals are partially or completely formed from plastic, and preferably comprise an epoxy material. Plastic seals can be manufactured cost-effectively and are available in large quantities and various designs. Epoxy material, such as epoxy resin, provides reliable protection against the ingress of moisture. Corresponding seals can also be produced by the injection of fluid plastic and a subsequent drying process, as a result of which complex geometries can also be sealed without great effort.

Additionally advantageous is a thermoelectric device according to the invention in which one, several, or all carrier substrates are designed to be elastically deformable. One, several, or all carrier substrates are preferably designed to be flexible. Alternatively or additionally, one, several, or all carrier substrates can be non-destructively, plastically deformable. Particularly preferred is that one, several, or all carrier substrates be designed to be bendable. This also allows the integration of corresponding thermoelectric devices in the region of bent surfaces. One, several, or all carrier substrates are, in particular, formed at least in sections from an elastically-deformable plastic.

Alternatively or additionally, one, several, or all carrier substrates can be formed at least in sections from an electrically-conductive and non-destructively-deformable material, such as a metal or a metal alloy, and can additionally have a dielectric and deformable insulation layer. For example, one, several, or all carrier substrates can be formed at least partially from copper or a copper alloy.

Also preferred is an embodiment of the thermoelectric device according to the invention in which one, several, or all carrier substrates are substantially free of ceramic material. The use of ceramic material results in a high brittleness of the corresponding carrier substrate, so that the risk of a brittle fracture during deformation of the thermoelectric device is increased. Since one, several, or all carrier substrates are substantially free of ceramic material, this risk is considerably reduced.

Another embodiment of the thermoelectric device according to the invention has one or more fastening means, which respectively extend through recesses, arranged in alignment with one another, of a carrier substrate arranged on the first side of the semiconductors and of a carrier substrate arranged on the second side of the semiconductors. The one or more fastening means can be designed, for example, as screws, pins, bolts, or clamps.

In an advantageous development of the thermoelectric device according to the invention, the thermoelectric device exclusively has fastening means surrounded by substrate material. Fastening the thermoelectric device by fastening means which are arranged on the edges of the thermoelectric device is thus avoided. In this way, a homogeneous voltage distribution over the individual carrier substrates of the thermoelectric device is achieved, whereby heat exchange is improved, and the risk of damage due to local voltage peaks is reduced.

In another preferred embodiment of the thermoelectric device according to the invention, no additional stabilizing pins or stabilizing webs are arranged between the at least one carrier substrate arranged on the first side of the semiconductors and the at least one carrier substrate arranged on the second side of the semiconductors. In this way, the material usage and the cost of manufacture are reduced. Additional stabilizing pins or stabilizing webs also lead to increased component complexity, which is overcome by dispensing with these elements.

In a development of the thermoelectric device according to the invention, at least one heat transfer device is respectively arranged on a side, opposite the semiconductors, of the carrier substrate arranged on the first side of the semiconductors, and/or on a side, opposite the semiconductors, of the one or more carrier substrates arranged on the second side of the semiconductors. The one or more heat transfer devices are preferably designed to absorb heat from the respective carrier substrate on which they are arranged and/or to deliver heat to the respective carrier substrate on which they are arranged. In particular, the one or more heat transfer devices are respectively formed of a heat-conducting material, such as a metal or a metal alloy. It is, moreover, preferred that the one or more heat transfer devices be each designed as flat plates and/or have the same base area as the respective carrier substrate on which they are arranged. A heat-conducting medium, such as a heat-conducting paste or a heat-conducting pad, can be arranged between the one or more heat transfer devices and the respective carrier substrate.

In another preferred embodiment of the thermoelectric device according to the invention, a, or an individual, or all heat transfer devices each have at least one recess which is designed to receive a fastening means. The one or more recesses are preferably formed as through-holes or blind holes. The one or more recesses may be used to attach the one or more heat transfer devices to the carrier substrates and the semiconductors. Since the one or more recesses are designed as through-holes, the need for an attachment arranged on the lateral edge or on the edges of the one or more heat transfer devices is overcome, so that the risk of damage in the edge region of the one or more heat transfer devices is substantially reduced. Furthermore, the one or more heat transfer devices can also be designed as heat exchangers.

Also advantageous is a thermoelectric device according to the invention in which the at least one recess of the at least one carrier substrate arranged on the first side of the semiconductors, the at least one recess of the at least one carrier substrate arranged on the second side of the semiconductors, and the at least one recess of the respective heat transfer devices are arranged in alignment with one another. As a result of the alignment of the recesses, the fastening means, such as screws, can extend through the aligned recesses, so that a stable and robust attachment of the carrier substrates and the heat transfer devices to one another can take place.

In another embodiment of the thermoelectric device according to the invention, the at least one recess of the respective heat transfer devices has a depression for receiving a head of a fastening means or a thread for screwing in a corresponding thread of a fastening means. The head of a fastening means can be lowered into the depression so that a flat object, e.g., a heat exchanger carrying a temperature control fluid, can be placed onto the outwardly-facing surface of the respective heat transfer device. The thread overcomes the need for the arrangement of a nut on the outwardly-facing surface of the respective heat transfer device. This also allows the provision of a planar outer surface of the respective heat transfer device, which allows the placement of a flat object, such as a heat exchanger carrying a temperature control fluid.

In an advantageous embodiment of the thermoelectric device according to the invention, a support device, which supports the carrier substrates and/or the heat transfer devices against one another, is arranged in the region of the recesses of the carrier substrates arranged on the first and second sides of the semiconductors. Without an appropriate support device, the clamping force of a fastening means would be transmitted largely or exclusively via the semiconductors. As a result of the resilience of the carrier substrates, the force necessary to transmit the load is applied predominantly to the semiconductors arranged in the region of the recesses. Experimental and simulative results have shown that the distribution of forces across the semiconductors mainly depends upon the stiffness of the heat transfer devices, the stiffness of the carrier substrates, the elasticity of the semiconductors, the distribution of the semiconductors and their distance to the force application point, and the elasticity of the heat-conducting media. A mechanical overload of the semiconductors can lead to damage or failure of a semiconductor. Particularly in the case of a series connection of the semiconductors, a significant functional impairment or a malfunction of the thermoelectric device thus occurs. The support device results in a reduction of the load on the semiconductors, so that the risk of damage and the risk of a malfunction at high clamping forces are considerably reduced.

The stiffness of the heat transfer devices and of the carrier substrates can be influenced by their thicknesses or material thicknesses, and/or their material elasticity. The elasticity of the semiconductors describes the resilience of the semiconductors under load. If the semiconductors are soft, the semiconductors yield directly at the force application point. As a result, adjacent semiconductors absorb a portion of the load. If the semiconductors are stiff, only the semiconductors directly at the force application point absorb the load. The stiffness of the semiconductors is determined by their material composition, which primarily aims at increasing the Seebeck coefficient. The distribution of the semiconductors and their distance from the force application point also have an influence. The more semiconductors that are positioned around the force application point, the lower the load on each individual semiconductor. The closer the semiconductors are to the force application point, the lower the torque which acts on the semiconductor edges. Accordingly, recesses formed as through-holes having a comparatively small radius positively affect the load distribution. The elasticity of the heat-conducting media helps to distribute the loads, in that the heat-conducting media yield locally and in this way transfer the force away from the load application point. In this case, a soft heat-conducting medium has a positive effect.

In another preferred embodiment of the thermoelectric device according to the invention, the one or more support devices are each designed to be annular and/or arranged to surround a fastening means. Annular support devices allow a particularly homogeneous flow of forces, so that stress peaks are reduced or avoided. The one or more annular support devices may have, for example, a round or polygonal inner surface and/or a round or polygonal outer surface. The one or more support devices preferably are at least the height of the semiconductors.

Alternatively, the one or more support devices may also have alternative shapes—for example, the shape of a rectangular box or cuboid. Furthermore, the one or more support devices may also comprise only individual ring segments. The one or more support devices may have a higher or lower stiffness and/or elasticity than the semiconductors. Alternatively, the stiffness and/or elasticity of the one or more support devices may substantially correspond to the stiffness and/or elasticity of the semiconductors.

In another development of the thermoelectric device according to the invention, the one or more support devices are respectively designed as an integral component of the carrier substrate arranged on the first side of the semiconductors and/or of the carrier substrate arranged on the second side of the semiconductors. The one or more support devices may alternatively also be designed to be separate from the carrier substrate arranged on the first side of the semiconductors and/or from the carrier substrate arranged on the second side of the semiconductors.

The aim underlying the invention is also achieved by a cup holder for a vehicle of the type mentioned at the outset, wherein at least one thermoelectric device is designed according to one of the above-described embodiments. With regard to the advantages and modifications of the cup holder according to the invention, reference is made to the advantages and modifications of the thermoelectric device according to the invention.

The aim underlying the invention is further achieved by a temperature control device for seats—in particular, vehicle seats—of the type mentioned at the outset, wherein at least one thermoelectric device is designed according to one of the above-described embodiments. With regard to the advantages and modifications of the temperature control device according to the invention, reference is made to the advantages and modifications of the thermoelectric device according to the invention.

The aim underlying the invention is further achieved by a method for producing a thermoelectric device of the type mentioned at the outset, wherein the thermoelectric device to be produced is designed according to one of the above-described embodiments, and a molded part is inserted into the one or more recesses before the several, differently-doped semiconductors are firmly bonded with the several electrically-conductive connectors arranged on the first carrier substrate and/or the second carrier substrate.

The electrically-conductive connectors could basically also be applied to a carrier substrate, or to a component whose temperature is to be controlled, or to a heat exchanger by additive methods, such as deposition, coating and/or pressing, or joining processes, such as gluing and/or soldering.

The electrically-conductive connectors may also be joined individually or as a contiguous film to the semiconductors, e.g., by soldering, wherein the carrier substrate can then be added later.

The thermoelectric device is supported by the inserted molded part during the firm bonding, so that the risk of damage due to a pressure load generated during the firm bonding is considerably reduced. This applies, in particular, to the sections in the region of the one or more recesses. The firm bonding can, in particular, include soldering—preferably, soft-soldering.

In an advantageous embodiment of the method according to the invention, the molded part is formed from rubber, plastic, and/or ceramic. In particular, the molded part is designed to be heat-resistant so that it is not damaged by the generated heat during the firm bonding.

In another embodiment of the method according to the invention, plastic—in particular, epoxy material—is injected between the first carrier substrate and the second carrier substrate —especially, in the area of the recesses—after the firm bonding of the several, differently-doped semiconductors with the several electrically-conductive connectors arranged on the first carrier substrate and/or the second carrier substrate. By injecting fluid plastic, the plastic can adapt to the shape to be sealed, and thus ensures effective protection against moisture ingress after drying.

Hereinafter, preferred embodiments of the invention are explained and described in more detail with reference to the accompanying drawings. Shown are:

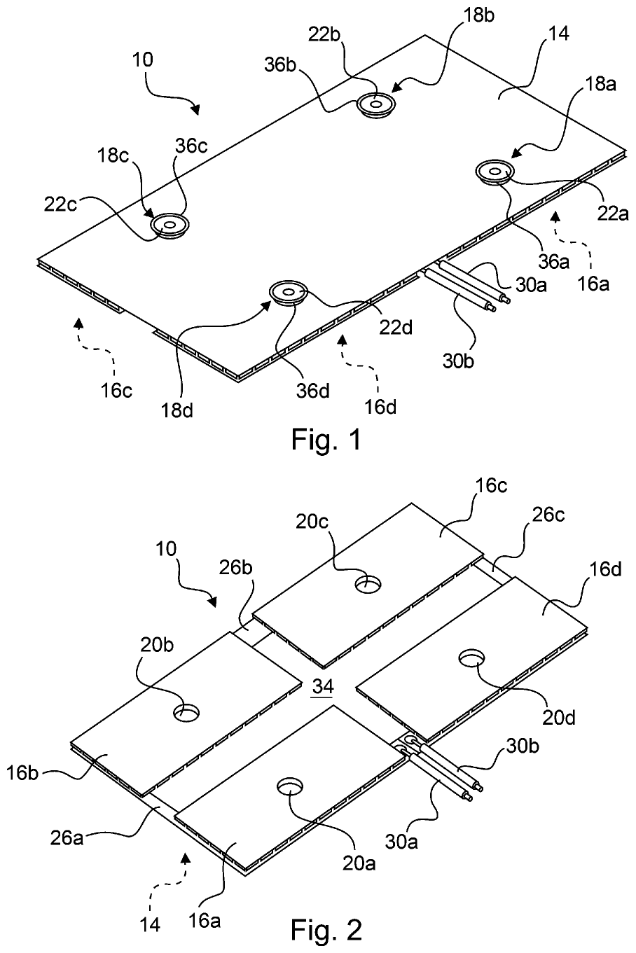

FIG. 1 an exemplary embodiment of the thermoelectric device according to the invention in a perspectival view;

FIG. 2 the thermoelectric device of FIG. 1 in a further perspectival view;

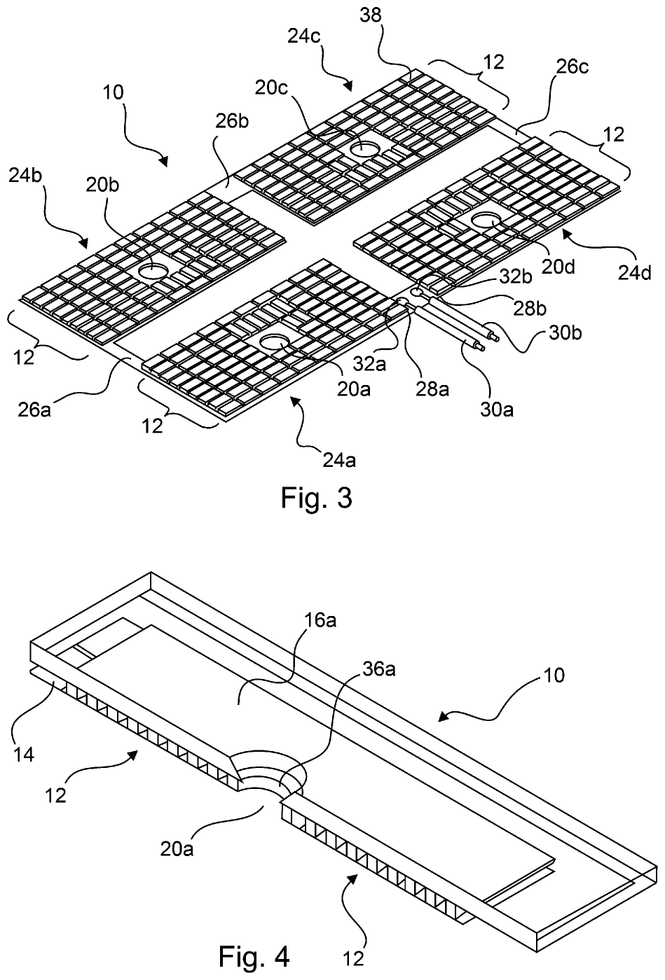

FIG. 3 parts of the thermoelectric device of FIG. 1 and FIG. 2 in a perspectival view;

FIG. 4 an exemplary embodiment of the thermoelectric device according to the invention in a sectional view;

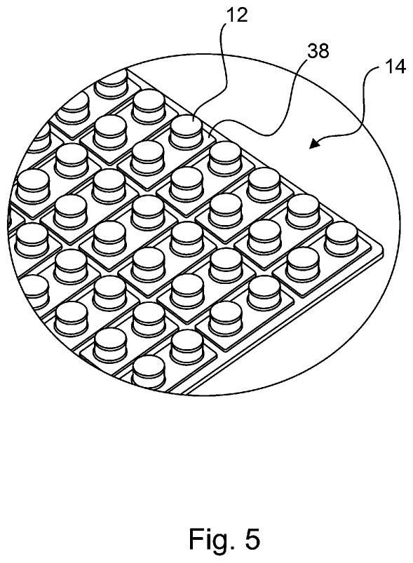

FIG. 5 an arrangement of semiconductors of a thermoelectric device according to the invention in a perspectival view;

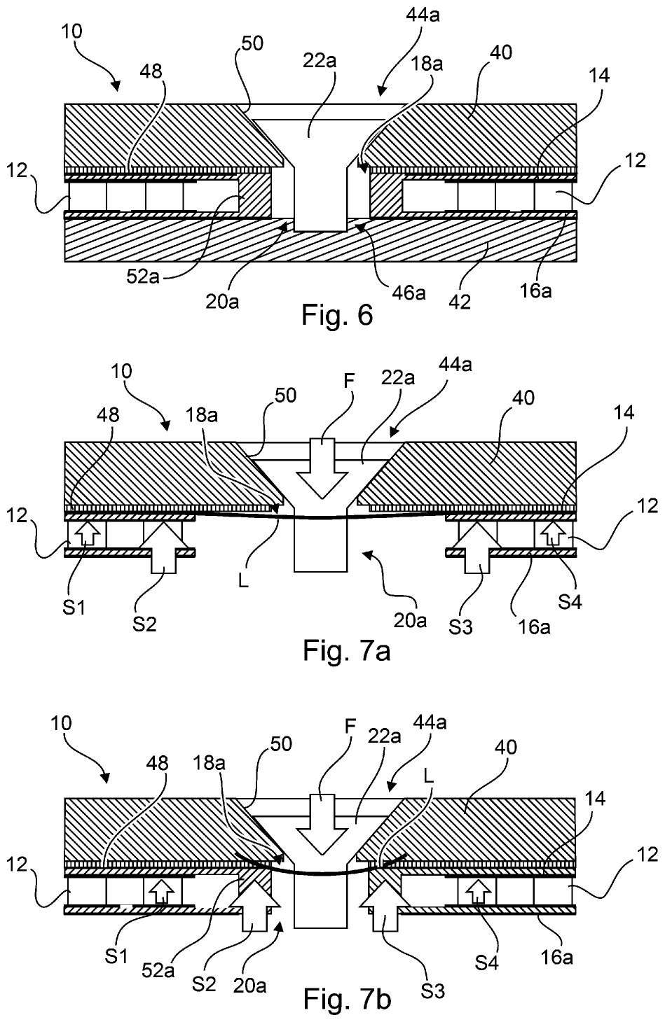

FIG. 6 parts of a thermoelectric device according to the invention in a sectional view;

FIG. 7a the load distribution in a thermoelectric device according to the invention in a sectional view;

FIG. 7b the load distribution in a further thermoelectric device according to the invention in a sectional view; and

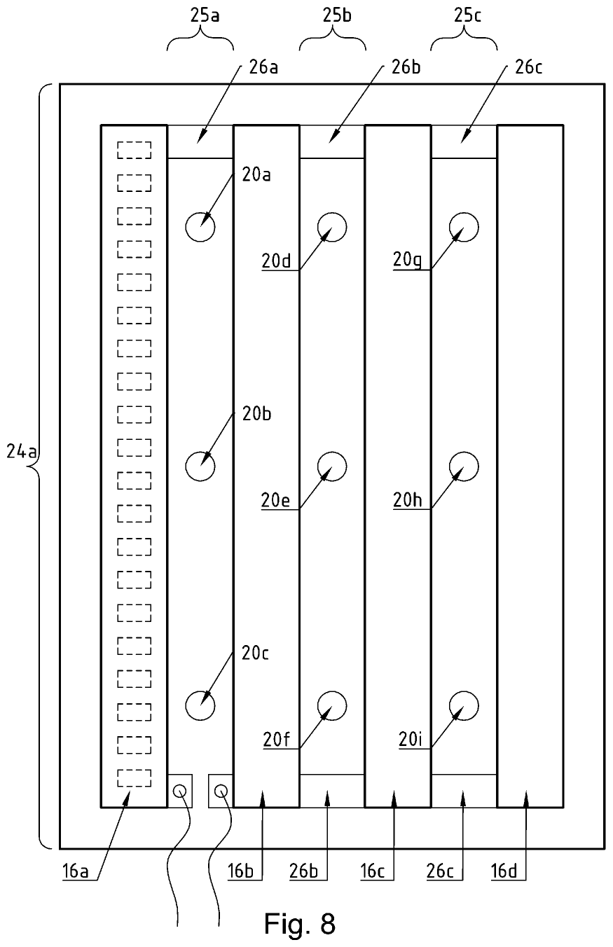

FIG. 8 a further embodiment of the thermoelectric device according to the invention.

FIG. 1 shows a thermoelectric device 10 having several, differently-doped and electrically-conductively interconnected semiconductors (concealed), a carrier substrate 14 arranged on a first side of the semiconductors 12, and a total of four carrier substrates 16a-16d arranged on a second side, opposite the first side, of the semiconductors 12. Consequently, the number of carrier substrates 14 arranged on the first side of the semiconductors 12 is smaller than the number of carrier substrates 16a-16d arranged on the second side of the semiconductors 12. All carrier substrates 14, 16a-16d are designed to be elastically deformable and substantially free of ceramic material.

The carrier substrate 14 arranged on the first side of the semiconductors 12 has a total of four recesses 18a-18d extending through the carrier substrate 14 and surrounded by substrate material. A fastening means 22a-22d respectively extends through the recesses 18a-18d, wherein the fastening means 22a-22d are designed as screws and are designed to be screwed to an object. The thermoelectric device 10 thus exclusively has fastening means 22a-22d surrounded by substrate material.

All recesses 18a-18d each have a seal 36a-36d, which substantially prevents the transport of moisture to the semiconductors 12. The seals 36a-36d are designed to be annular, and each support a carrier substrate 14 arranged on the first side of the semiconductors 12 and a carrier substrate 16a-16d on the second side of the semiconductors 12 against one another. The seals 36a-36d are, furthermore, formed entirely of plastic, the plastic comprising an epoxy material.

The several, differently-doped and electrically-conductively interconnected semiconductors 12 are electrically-conductively connected to the electrical conductors 30a, 30b. Via the electrical conductors 30a, 30b, a voltage may, for example, be applied or tapped.

FIG. 2 shows that the four carrier substrates 16a-16d arranged on the second side of the semiconductors 12 each have a recess 20a-20d extending through the carrier substrate 16a-16d and surrounded by substrate material. The number of recesses 18a-18d of the carrier substrate 14 arranged on the first side of the semiconductors 12 and the number of recesses 20a-20d of the carrier substrates 16a-16d arranged on the second side of the semiconductors 12 are consequently identical. The recesses 20a-20d are designed to receive the fastening means 22a-22d shown in FIG. 1.

The four recesses 20a-20d of the several carrier substrates 16a-16d arranged on the second side of the semiconductors 12 are arranged substantially in the center of the respective carrier substrate 16a-16d. The four recesses 18a-18d of the carrier substrate 14 arranged on the first side of the semiconductors 12 and the four recesses 20a-20d of the four carrier substrates 16a-16d arranged on the second side of the semiconductors 12 are arranged in alignment with one another.

The four carrier substrates 16a-16d arranged on the second side of the semiconductors 12 are spaced apart from one another and respectively arranged in a corner of the thermoelectric device 10.

In conjunction with FIG. 3, it becomes clear that the four carrier substrates 16a-16d arranged on the second side of the semiconductors 12 each extend over a semiconductor group 24a-24d. Each semiconductor group 24a-24d comprises a quarter of the semiconductors 12 of the thermoelectric device 10. The four semiconductor groups 24a-24d thus have an identical number of semiconductors 12. The semiconductor groups 24a-24d also respectively extend over an area of the same size.

The first semiconductor group 24a is electrically-conductively connected to the terminal 28a, wherein said terminal 28a is electrically-conductively connected to the electrical conductor 30a via the solder connection 32a. The first semiconductor group 24a is, furthermore, electrically-conductively connected to the second semiconductor group 24b via the group-connecting bridge 26a. The second semiconductor group 24b is electrically-conductively connected to the third semiconductor group 24c via the group-connecting bridge 26b. The third semiconductor group 24c is electrically-conductively connected to the fourth semiconductor group 24d via the group-connecting bridge 26c. The fourth semiconductor group 24d is electrically-conductively connected to the terminal 28b, wherein said terminal 28b is electrically-conductively connected to the electrical conductor 30b via the solder connection 32b.

As can be seen in FIG. 2, the semiconductor groups 24a-24d are circumferentially sealed with a sealing material 34, which substantially prevents the transport of moisture to the semiconductors 12. Arranged between adjacent semiconductor groups 24a-24d is also sealing material 34, which also substantially prevents the transport of moisture to the semiconductors 12. The sealing material 34 is formed as silicone.

FIG. 3 moreover shows that no additional stabilizing pins or stabilizing bars are arranged between the carrier substrate 14 arranged on the first side of the semiconductors 12 and the carrier substrates 16a-16d arranged on the second side of the semiconductors 12.

FIG. 4 and FIG. 5 show the arrangement of the semiconductors 12 and the metallic connectors 38 electrically-conductively connected to the semiconductors 12. The semiconductors of a semiconductor group 24a-24d are equidistantly spaced from one another. The metallic connectors 38 each electrically-conductively interconnect two semiconductors 12 of a semiconductor group 24a-24d, so that a current flow through all semiconductors 12 of a semiconductor group 24a-24d can be realized. Together with the terminals 28a, 28b and the group-connecting bridges 26a-26c, a current flow through all semiconductors 12 of the thermoelectric device can be implemented.

FIG. 6 shows a thermoelectric device 10 having several, differently-doped and electrically-conductively interconnected semiconductors 12. On a first side of the semiconductors 12 is arranged a carrier substrate 14. On a second side of the semiconductors 12 are arranged a total of four carrier substrates, of which the carrier substrate 16a is shown. On the side of the carrier substrate 14 opposite the semiconductors 12, and on the side of the carrier substrate 16a opposite the semiconductors 12, a heat transfer device 40, 42 is respectively arranged. The heat transfer devices 40, 42 are shaped as flat plates and designed to dissipate heat from the respective carrier substrate 14, 16a or to supply heat to the respective carrier substrate 14, 16a.

Between the carrier substrate 14 and the heat transfer device 40, a heat-conducting medium 48 is arranged, which promotes the heat exchange between the carrier substrate 14 and the heat transfer device 40. The heat-conducting medium 48 is designed as a heat-conducting pad. The heat transfer devices 40, 42 and the carrier substrates 14, 16a have recesses 44a, 46a, 18a, 20a which are in alignment with one another and through which a fastening means 22a designed as a screw extends. The recesses 18a, 20a of the carrier substrates 14, 16a are designed as through-holes and have a substantially round cross-section. The recess 44a of the heat transfer device 40 is also designed as a through-hole, but has a depression 50. The depression 50 serves to receive the head of the fastening means 22a. The recess 46a of the heat transfer device 42 is formed as a blind hole and has a thread. A corresponding thread of the fastening means 22a is screwed into the thread in the recess 46a.

A support device 52a is arranged in the region of the recesses 18a, 20a of the carrier substrates 14, 16a arranged on the first and second sides of the semiconductors 12. The support device 52a is designed to be annular and surrounds the fastening means 22a. The support device 52a serves to support the carrier substrates 14, 16a and the heat transfer devices 40, 42 against one another, and is designed as an integral component of the carrier substrate 14 and of the carrier substrate 16a.

FIG. 7a and FIG. 7b show the influence of a support device 52a on the load distribution L in the region of the recesses 44a, 46a, 18a, 20a.

The thermoelectric device 10 shown in FIG. 7a has no support device. In this case, the clamping force F of the fastening means 22a is absorbed exclusively by the semiconductors 12. In this case, comparatively large supporting forces S2, S3 act on the semiconductors 12 arranged directly on the fastening means 22a. Lower supporting forces S1, S4 act on the semiconductors 12, which are arranged in the second row behind the fastening means 22a. The semiconductors 12 which are arranged directly on the fastening means 22a and on which the supporting forces S2, S3 act, are subjected to a high mechanical load. Due to the high mechanical load, there is an increased risk of damage and failure in comparison to the embodiment shown in FIG. 7b.

The thermoelectric device 10 shown in FIG. 7b has an annular support device 52a surrounding the fastening means 22a. In this case, the clamping force F of the fastening means 22a is largely absorbed by the support device 52a. In this case, comparatively large supporting forces S2, S3 act on the support device 52a. Only smaller supporting forces 51, S4 act on the semiconductors 12, which are arranged behind the support device 52a. Since the clamping force F is absorbed largely by the support device 52a, the semiconductors 12 are subjected to only a low mechanical load, which considerably reduces the risk of damage and failure. A particularly preferred arrangement for semiconductor groups 24a-24d is shown in FIG. 8. Accordingly, a carrier substrate 16 is equipped with a plurality of semiconductors 12 in the manner described above. In this case, the semiconductors 20 are arranged in several semiconductor groups 24a-24d. The semiconductor groups 24a-24d are preferably arranged next to one another in a constant length and width. They are each covered by a strip-shaped, covering carrier substrate 16a-16d.

Two semiconductor groups 24a-24d each are respectively spaced apart from one another by an interjacent separation zone 25a-25c and interconnected by a group-connecting bridge 26a-26c. It can be provided in this case that two semiconductor groups 24a-24d also be interconnected via several group-connecting bridges 26a-c or that at least one semiconductor group 24a-24d also be connected to several other semiconductor groups 24a-24d. The interconnection preferably takes place such that a closed conductor loop is formed. As a result, all semiconductors 12 of the thermoelectric device 10 are, preferably, electrically contacted with only two terminals 28a, b. In this arrangement, the covering carrier substrates 16a-16d are arranged to be substantially parallel to one another and respectively separated from one another by a distance.

The attachment of the thermoelectric device is effected by fastening pins (e.g., screws) penetrating and holding the carrier substrate 14 at a plurality of recesses 20a-20i.

At least one recess 20a-20i is provided in at least one separation zone 25a-25c. At least one recess 20a-20i is preferably provided in at least two or more separation zones 25a-25c. In at least one separation zone 25a-25c are preferably provided at least two or more recesses 20a-20i.

At least two or more recesses 20a-20i are preferably provided in at least two or more separation zones 25a-25c.

In contrast thereto, no recess 20a-i is provided in the region of at least one semiconductor group. All existing semiconductor groups 24a-c are, preferably, free of recesses 20a-20i. This is because penetration in the region of the semiconductor groups or of the covering carrier substrates 16a-16d is not necessary for holding the carrier substrate 14 and evenly distributing its load.

Since the fastening pins and the plurality of recesses 20a-20i in this embodiment penetrate only the carrier substrate 14, sealing the recesses 20a-20i and its support can be omitted.

This simplifies production and increases the strength of the thermoelectric device.

The holding is, expediently, carried out by clamping the thermoelectric device between two metal plates (for example, heat exchanger plates). This results in an even frictional clamping and a positive fixation relative to the plane of the carrier substrate.

### REFERENCE SIGNS

10 Thermoelectric device
12 Semiconductor
14 Carrier substrate
16a-16d Carrier substrates
18a-18d Recesses
20a-20i Recesses
22a-22d Fastening means
24a-24d Semiconductor group
25a-25c Separation zone
26a-26c Group-connecting bridges
28a, 28b Terminals
30a, 30b Electrical conductor
32a, 32b Solder connection
34 Sealing material
36a-36d Seals
38 Connector
40 Heat transfer device
42 Heat transfer device
44a Recess
46a Recess
48 Heat-conducting medium
50 Depression
52a Support device
L Load distribution
F Clamping force
S1-S4 Supporting forces

1. Thermoelectric device comprising:
several, differently-doped and electrically-conductively interconnected semiconductors,
at least one carrier substrate arranged on a first side of the semiconductors, and
at least one carrier substrate arranged on a second side, opposite the first side, of the semiconductors,
wherein the at least one carrier substrate arranged on the first side or the second side of the semiconductors has at least one recess which extends through the carrier substrate and is surrounded by substrate material, and which is designed to receive a fastening means.

2. The thermoelectric device according to claim 1, wherein the at least one carrier substrate arranged on the first side of the semiconductors and the at least one carrier substrate arranged on the second side of the semiconductors respectively have at least one recess which extends through the at least one carrier substrate arranged on the first side and the second side and is surrounded by a substrate material, and which includes a fastening means, and wherein the at least one recess of the at least one carrier substrate arranged on the first side of the semiconductors and the at least one recess of the at least one carrier substrate arranged on the second side of the semiconductors are arranged in alignment with one another.

3. (canceled)

4. (canceled)

5. The thermoelectric device according to claim 1, wherein several of the at least one carrier substrates are arranged on the first side of the semiconductors and/or on the second side of the semiconductors, and wherein a number of the several of the at least one carrier substrates arranged on the first side of the semiconductors is smaller than a number of carrier substrates arranged on the second side of the semiconductors.

6. (canceled)

7. The thermoelectric device according to claim 5, wherein a number of recesses of the at least one carrier substrate arranged on the first side of the semiconductors and a number of recesses of the several of the at least one carrier substrates arranged on the second side of the semiconductors are identical.

8. The thermoelectric device according to claim 5, the several of the at least one carrier substrates arranged on the second side of the semiconductors respectively have only one recess and that the recesses of the several carrier substrates arranged on the second side of the semiconductors are arranged substantially in a center of the respective carrier substrate.

9. (canceled)

10. The thermoelectric device according to claim 5, wherein the several of the at least one carrier substrates arranged on the second side of the semiconductors respectively extend over a semiconductor group, and several or all of the semiconductor group respectively extend over an area of the same size and/or have an identical number of semiconductors.

11. (canceled)

12. (canceled)

13. The thermoelectric device according to claim 10, wherein several or all of the semiconductor group are circumferentially sealed with a sealing material which reduces or prevents transport of moisture to the semiconductors.

14. The thermoelectric device according to claim 10, wherein a sealing material is arranged between adjacent ones of the semiconductor groups, the sealing material reducing or preventing transport of moisture to the semiconductors.

15. The thermoelectric device according to claim 13, wherein the sealing material is designed as silicone or comprises silicone.

16. The thermoelectric device according to claim 1, wherein one of the at least one recess, several, or all of the at least one recesses respectively have a seal which reduces or prevents transport of moisture to the semiconductors.

17. (canceled)

18. The thermoelectric device according to claim 16, wherein the one or more seals respectively support the at least one carrier substrate arranged on the first side of the semiconductors and the at least one carrier substrate arranged on the second side of the semiconductors against one another.

19. The thermoelectric device according to claim 16, wherein the one or more seals are partially or completely formed from plastic, and one, several, or all of the at least one carrier substrates are elastically deformable.

20. (canceled)

21. The thermoelectric device according to claim 1, wherein one, several, or all of the at least one carrier substrates are substantially free of ceramic material; wherein one or more fastening means, which respectively extend through the at least one recesses, arranged in alignment with one another, of the at least one carrier substrate arranged on the first side of the semiconductors and of the at least one carrier substrate arranged on the second side of the semiconductors; or both.

22. (canceled)

23. The thermoelectric device according to claim 1, wherein the thermoelectric device exclusively has fastening means surrounded by substrate material, and no additional stabilizing pins or stabilizing bars are arranged between the at least one carrier substrate arranged on the first side of the semiconductors and the at least one carrier substrate arranged on the second side of the semiconductors.

24. (canceled)

25. The thermoelectric device according to claim 1, wherein at least one heat transfer device is respectively arranged on a side, opposite the semiconductors, of the at least one carrier substrate arranged on the first side of the semiconductors and/or on a side, opposite the semiconductors, of the one or more carrier substrates arranged on the second side of the semiconductors.

26. (canceled)

27. The thermoelectric device according to claim 1, wherein the at least one recess of the at least one carrier substrate arranged on the first side of the semiconductors, the at least one recess of the at least one carrier substrate arranged on the second side of the semiconductors, and the at least one recess of the respective heat transfer devices are arranged in alignment with one another, and the at least one recess of the respective heat transfer devices has a depression for receiving a head of a fastening means or a thread for screwing in a corresponding thread of a fastening means.

28. (canceled)

29. (canceled)

30. (canceled)

31. (canceled)

32. A cup holder for a vehicle, comprising:
a receiving device, which is designed to receive a drinking vessel and provides a temperature control space for the drinking vessel; and
one or more thermoelectric devices, which are coupled with the temperature control space in a heat-transferring manner;
wherein the at least one thermoelectric device is designed according to claim 1.

33. A temperature control device for vehicle seats comprising:
a conveying device designed to convey a fluid to a temperature control area; and
a temperature control device which has one or more thermoelectric devices of claim 1 and is is configured to control the temperature of the fluid to be conveyed to the temperature control area.

34. A method for producing a thermoelectric device according to claim 1 comprising:
firmly bonding the several, differently-doped semiconductors with several electrically-conductive connectors arranged on a first carrier substrate, and
firmly bonding the several, differently-doped semiconductors with several electrically-conductive connectors arranged on a second carrier substrate,
wherein a molded part is inserted into the one or more recesses before the several, differently-doped semiconductors are firmly bonded with the several electrically-conductive connectors arranged on the first carrier substrate and/or the second carrier substrate.

35. (canceled)

36. The method according to claim 34, wherein plastic is injected between the first carrier substrate and the second carrier substrate after the several, differently-doped semiconductors are firmly bonded with the several electrically-conductive connectors arranged on the first carrier substrate and/or the second carrier substrate.
